(19) United States
(12) Patent Application Publication
(10) Pub. No.: US 2025/0172963 A1
(43) Pub. Date: May 29, 2025

(54) PHASE ALIGNMENT CIRCUITRY

(71) Applicant: Cirrus Logic International Semiconductor Ltd., Edinburgh (GB)

(72) Inventors: Luis GOMEZ DURAN, Edinburgh (GB); Michael CHANDLER-PAGE, Newbury (GB); Erich P. ZWYSSIG, Edinburgh (GB)

(73) Assignee: Cirrus Logic International Semiconductor Ltd., Edinburgh (GB)

(21) Appl. No.: 18/907,479

(22) Filed: Oct. 5, 2024

Related U.S. Application Data
(60) Provisional application No. 63/602,776, filed on Nov. 27, 2023.

(30) Foreign Application Priority Data
Dec. 14, 2023 (GB) 2319101.8

(51) Int. Cl. G06F 1/08; G06F 1/12; H03L 7/08

(52) U.S. Cl. CPC G06F 1/08; G06F 1/12; H03L 7/08

(57) ABSTRACT

Circuitry for aligning a phase of an output signal with a phase of an input clock signal, the circuitry being operable in one of a plurality of phase alignment modes, wherein the plurality of phase alignment modes comprises two or more of: a single step alignment mode; a multiple step alignment mode; and a random or pseudo-random step alignment mode.

### FIELD OF THE INVENTION

The present disclosure relates to phase alignment circuitry for aligning a phase of an output signal with a phase of a received input clock signal.

### BACKGROUND

Digital audio interfaces are used to couple digital audio devices or integrated circuits together to permit the transmission of digital audio data from one device or integrated circuit to another. Such interfaces typically have an audio data line for carrying an output stream of digital audio data, a bit clock line for carrying an output bit clock (BCLK) signal, and a frame synchronisation line for carrying an output frame synchronisation (FSYNC) signal. The stream of digital audio data typically comprises a stream of serial data bits encoding one or more channels of audio data. The stream of serial data bits is divided into frames of audio data, each frame comprising a predefined number N of bits (e.g. 16, 32 or 64 bits). One output audio data bit is transmitted on the audio data line per period of the bit clock signal. Thus, for a single-channel data stream one cycle of the frame synchronisation signal FSYNC will have a duration equal to N×the period of the bit clock signal BCLK. For a two-channel data stream (as supported by the I2S protocol, for example), 2N data bits are transmitted per frame synchronisation period (N data bits per channel) such that the frame synchronisation signal FSYNC will have a duration equal to 2N×the period of the bit clock signal BCLK. A transition (e.g. from logic low to logic high or vice versa) in the frame synchronisation signal FSYNC indicates the beginning of a frame of audio data on the audio data line.

In digital audio systems that use such digital audio interfaces, data converters (such as digital to analog converters (DACs) used for converting a received digital signal into an analog output signal and analog to digital converters (ADCs) used for converting a received analog signal into a digital output signal) are typically clocked with a master clock signal MCLK having a frequency that is a high power of two multiple of a sample rate Fₛ of a digital audio signal being transmitted by the system. For example, where a sample rate Fₛ of 48 KHz is used, the frequency of the master clock signal may be 24.576 MHz (=2⁹×48 KHz). The master clock signal MCLK provides a fundamental frequency reference for such data converters.

The master clock signal MCLK is typically generated by clock generation circuitry based on an input clock signal CLK_IN that is received with or recovered from an input digital audio data stream of the kind described above. The received or recovered input clock signal CLK_IN is typically affected by jitter. The bit clock signal BCLK transmitted on the bit clock line of the digital audio interface may be derived from or based on the master clock signal. For example, the period of a cycle of the bit clock signal BCLK may be an integer multiple of a period of the master clock signal MCLK.

For accurate output of an audio signal, a phase of the output frame synchronisation signal FSYNC should be aligned with a phase of the input clock signal CLK_IN, in the sense that a transition (e.g. from low to high) in the output frame synchronisation signal FSYNC should always occur within a defined maximum time period of a corresponding transition in the input clock signal CLK_IN, such that a time offset (or phase alignment error) between a transition in the input clock signal CLK_IN and a corresponding transition in the output frame synchronisation signal FSYNC is always equal to or less than the defined maximum time period.

FIG. 1 is a timing diagram showing correct phase alignment between the input clock signal CLK_IN and the output frame synchronisation signal FSYNC. As can be seen in FIG. 1, a rising edge of a pulse 110 of the output frame synchronisation signal FSYNC lags a rising edge of a pulse 120 of a first cycle of the input clock signal CLK_IN by half the period of the master clock signal MCLK. In a subsequent cycle of the input clock signal CLK_IN, a rising edge of a subsequent pulse 130 of the output frame synchronisation signal also lags the rising edge of a corresponding pulse 140 of the input clock signal CLK_IN by half the period of the master clock signal MCLK. Thus, for each cycle of the input clock signal CLK_IN, there is a uniform delay of half the period of the master clock signal MCLK between a pulse of the input clock signal CLK_IN and a corresponding pulse of the output frame synchronisation signal FSYNC.

Any loss of such phase alignment between the input clock signal CLK_IN and the frame synchronisation signal FSYNC (which could arise, for example, as a result of the temporary loss of the input clock signal CLK_IN) would lead to audible deterioration of the quality of an audio signal decoded using the transmitted bit clock BCLK and frame synchronisation FSYNC signals.

### SUMMARY

According to a first aspect, the invention provides circuitry for aligning a phase of an output signal with a phase of an input clock signal, the circuitry being operable in one of a plurality of phase alignment modes, wherein the plurality of phase alignment modes comprises two or more of: a single step alignment mode; a multiple step alignment mode; and a random or pseudo-random step alignment mode.

The output signal may comprise a frame synchronisation output signal.

The output signal may comprise a bit clock output signal.

The circuitry may comprise phase alignment circuitry configured to: determine a phase difference between a cycle of the input clock signal and a cycle of the output signal; and apply one or more correction steps to correct the determined phase difference.

The phase alignment circuitry may be configured to count a number of cycles of a master clock signal between an edge of the output signal and a corresponding edge of the input clock signal.

In the single step alignment mode, the phase alignment circuitry may be operative to extend a period of a single subsequent cycle of the output signal by a applying a single correction step having a duration corresponding to the determined phase difference.

The period of the single subsequent cycle may be extended by applying the single correction step to a single cycle of an output clock signal upon which the output signal is based.

The output signal may be an output frame synchronisation signal, and the output clock signal may be an output bit clock signal.

In the multiple step alignment mode the phase alignment circuitry may be operable to: extend a period of each of one or more subsequent cycles of the output signal by applying a correction step having a duration that does not correspond to the determined phase difference.

In the multiple step alignment mode the phase alignment circuitry may be operative to: determine a correction step to be applied to a next cycle of the output signal to extend the period of the next cycle, based on a minimum between a predetermined correction step value and a value of a remaining phase difference between the cycle of the input clock signal and a cycle of the output signal.

The period of the next cycle of the output signal may be extended by applying the determined correction step to a cycle of an output clock signal upon which the output signal is based within the period of the next cycle of the output signal.

The phase alignment circuitry may comprise a random noise source for randomly or pseudo-randomly selecting the cycle of the output clock signal to which the determined correction step is applied.

The random noise source may comprise a noise shaped random noise source such as a sigma-delta modulator.

In the random or pseudo-random step alignment mode the phase alignment circuitry may be operative to: extend a period of each of one or more subsequent cycles of the output signal by applying a correction step having a randomly or pseudo-randomly selected duration.

In the random or pseudo-random step alignment mode the phase alignment circuitry may be operative to: determine a correction step to be applied to a next cycle of the output signal to extend the period of the next cycle, based on a minimum between a randomly or pseudo-randomly selected correction step duration and a duration of a remaining phase difference between the cycle of the input clock signal and a cycle of the output signal.

The circuitry may further comprise clock generator circuitry configured to receive the input clock signal and a frequency reference signal and to generate an output clock signal having a frequency of the input clock signal and jitter characteristics of the frequency reference signal.

The clock generator circuitry may comprise hybrid phase locked loop circuitry comprising an analog phase locked loop having a feedback path comprising a digital frequency locked loop.

The circuitry may be configured to generate a master clock signal based on the output clock signal generated by the clock generator circuitry.

The circuitry may be configured to generate a master clock signal. A duration of the one or more correction steps may be based on a period of the master clock signal.

According to a second aspect, the invention provides an integrated circuit comprising circuitry according to the first aspect.

According to a third aspect, the invention provides a host device comprising circuitry according to the first aspect.

The host device may comprise a laptop, notebook, netbook or tablet computer, a gaming device, a games console, a controller for a games console, a virtual reality (VR) or augmented reality (AR) device, a mobile telephone, a portable audio player, a portable device, an automotive device, an automotive audio system, an accessory device for use with a laptop, notebook, netbook or tablet computer, a gaming device, a games console a VR or AR device, a mobile telephone, a portable audio player or other portable device.

According to a fourth aspect, the invention provides clock generator integrated circuit having: an input for receiving an input clock signal; a first output for outputting a bit clock output signal; and a second output for outputting a frame synchronisation signal, wherein the clock generator integrated circuit is configured to maintain a phase alignment between the input clock signal and the frame synchronisation output signal, and/or between the input clock signal and the bit clock output signal.

According to a fifth aspect, the invention provides phase alignment circuitry for aligning a phase of an output signal with a phase of an input clock signal, the phase alignment circuitry being configured to: determine a phase difference between a cycle of the input clock signal and a cycle of the output signal; and extend a period of each of one or more subsequent cycles of the output signal by applying a correction step having a randomly or pseudo-randomly selected duration, to align a phase of the output signal with a phase of the input signal.

According to a sixth aspect, the invention provides phase alignment circuitry for aligning a phase of an output signal with a phase of an input clock signal, the phase alignment circuitry being configured to: determine a phase difference between a cycle of the input clock signal and a cycle of the output signal; and extend a period of each of one or more subsequent cycles of the output signal by applying a correction step having a duration that does not correspond to the determined phase difference to a cycle of an output clock signal upon which the output signal is based within the period of the next cycle of the output signal, wherein phase alignment circuitry is configured to select the cycle of the output clock signal to which the correction step is applied randomly or pseudo-randomly.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is a timing diagram showing correct phase alignment between an input clock signal CLK_IN and an output frame synchronisation signal FSYNC in a digital audio system;

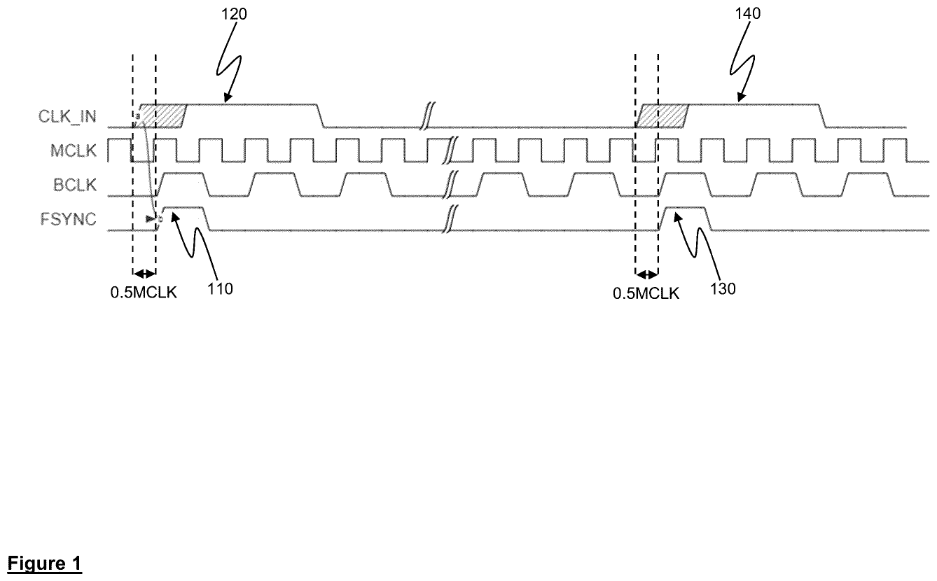

FIG. 2 is a simplified schematic diagram showing circuitry incorporating phase alignment circuitry according to the present disclosure;

FIG. 3 is a timing diagram showing correction of phase misalignment between an input clock signal CLK_IN and an output frame synchronisation signal FSYNC in a single step;

FIG. 4 is a flow diagram illustrating steps performed by the phase alignment circuitry of the circuitry of FIG. 2 when operating in a second mode of operation;

FIG. 5a is a timing diagram showing extension of consecutive periods of an output clock signal to correct a phase error between an input clock signal and an output signal

FIG. 5b schematically illustrates unwanted spectral components that may arise from the use of correction steps of fixed duration in the phase alignment circuitry of FIG. 2;

FIG. 5c schematically illustrates spectral noise that may arise from the use, in the phase alignment circuitry of FIG. 2, of randomly or pseudo-randomly positioned correction steps of fixed duration in the phase alignment circuitry of FIG. 2;

FIG. 6 schematically illustrates shaped spectral noise that may arise from the use, in the phase alignment circuitry of FIG. 2, of randomly or pseudo-randomly positioned correction steps of fixed duration, where the phase alignment circuitry includes a noise shaped random source; and

FIG. 7 is a flow diagram illustrating steps performed by the phase alignment circuitry of the circuitry of FIG. 2 when operating in a third mode of operation.

### DETAILED DESCRIPTION

The present disclosure relates to phase alignment circuitry for maintaining and recovering alignment between an input clock signal and an output signal, for example for use in a digital audio system to maintain and recover phase alignment between an input clock signal and an output frame synchronisation signal.

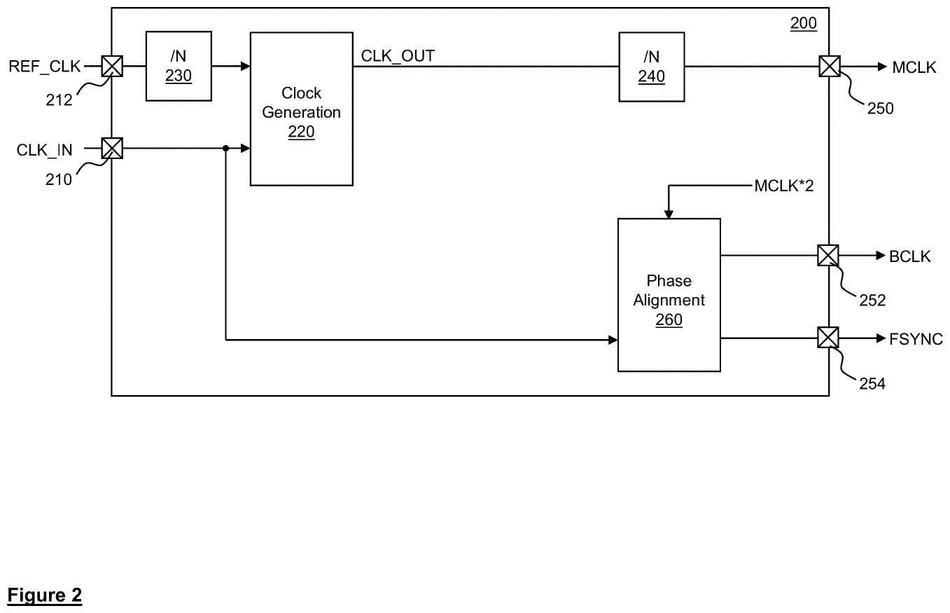

FIG. 2 is a simplified schematic diagram showing circuitry 200 incorporating phase alignment circuitry according to the present disclosure. The circuitry 200 may be implemented as an integrated circuit (IC), for example.

The circuitry 200 has a first input terminal 210 for receiving an input clock signal CLK_IN, which may have been derived or recovered from an audio input signal to be transmitted by a digital audio system incorporating the circuitry 200, or may have been received with such an input audio signal. The first input terminal 210 is coupled to a first input of clock generation circuitry 220 such that the input clock signal CLK_IN is supplied to the clock generation circuitry 220.

The circuitry 200 has a second input terminal 212 for receiving a high quality reference clock signal REF_CLK, e.g. from a crystal oscillator or other stable timing reference external to the circuitry 200. The second input terminal 212 is coupled to a second input of the clock generation circuitry 220 (via first frequency divider circuitry 230 in the example shown in FIG. 2), such that the high quality clock signal REF_CLK (or a high quality clock signal derived from or based on REF_CLK) is supplied to the clock generation circuitry 220.

The clock generation circuitry 220 is configured to generate an output clock signal CLK_OUT which may be frequency divided (e.g. by 2) by second frequency divider circuitry 240 to generate an output master clock signal MCLK for downstream components of a host device incorporating the circuitry 200, such as DACs or ADCs. In the example shown in FIG. 2, an output of the second frequency divider circuitry is coupled to a first output terminal 250 of the circuitry 200. In other examples the output clock signal CLK_OUT generated by the clock generation circuitry 220 may be suitable for use as the master clock signal MCLK. In such examples the second frequency divider circuitry 240 is omitted and an output of the clock generation circuitry 220 is coupled to the first output terminal 250.

In some examples the clock generation circuitry 220 may comprise hybrid phase locked loop circuitry comprising an analog phase locked loop (PLL) and a digital frequency locked loop (FLL) in a feedback signal path of the digital PLL. The hybrid phase locked loop circuitry is configured to receive the high quality clock signal REF_CLK and the input clock signal CLK_IN and to generate an output clock signal CLK_OUT at the frequency of the input clock signal CLK_IN with the jitter characteristics of the high quality clock signal REF_CLK.

The first input terminal 210 is also coupled to an input of phase alignment circuitry 260, which also receives a clock signal MCLK*2 having a frequency which in this example is twice the frequency of the master clock signal MCLK. The received clock signal MCLK*2 is thus indicative of the master clock signal MCLK. The clock signal MCLK*2 may be provided by or derived from the output clock signal CLK_OUT generated by the clock generation circuitry 220, for example.

The phase alignment circuitry 260 is configured to generate a frame synchronisation output signal FYSNC and a bit clock output signal BCLK. A first output of the phase alignment circuitry 260 is coupled to a second output terminal 252 of the circuitry 200, such that the bit clock output signal BCLK is supplied to the second output terminal 252. A second output of the phase alignment circuitry 260 is coupled to a third output terminal 254 of the circuitry 200, such that the frequency synchronisation output signal FSYNC is supplied to the third output terminal 254.

The phase alignment circuitry 260 is configured to maintain and if necessary recover phase alignment between the input clock signal CLK_IN and an output frame synchronisation signal FSYNC. The number of bit clock output signal BCLK cycles per frame synchronisation output signal FSYNC remains constant, such that if the frame synchronisation output signal FSYNC is resynchronised to a new input clock signal CLK_IN, the period of one or more bit clock output signal BCLK cycles is extended to achieve a constant number of bit clock output signal BCLK cycles per frame synchronisation output signal FSYNC.

To this end, the phase alignment circuitry 260 is configured to measure a phase difference phase_diff between a pulse of the input clock signal CLK_IN and a corresponding pulse of the output frame synchronisation signal FSYNC, and to compare the measured phase difference phase_diff to a predefined threshold phase_th. If the measured phase difference phase_diff is greater than the predefined threshold phase_th, the phase alignment circuitry 260 is operative to adjust the duration of one or more subsequent frame synchronisation signal periods (where a frame synchronisation signal period or FSYNC period is the period between a pulse of the frame synchronisation signal FSYNC and a subsequent pulse of the frame synchronisation signal FSYNC) to compensate for the phase difference phase_diff to restore phase alignment between the input clock signal CLK_IN and the output frame synchronisation signal FSYNC.

In a first mode of operation, the phase alignment circuitry 260 is operable to measure the phase difference phase_diff by counting a number of cycles of the master clock MCLK between an edge (e.g. a rising edge) of the frame synchronisation signal FSYNC and a corresponding edge of the input clock signal CLK_IN. The phase alignment circuitry 260 is operative to compare the resulting count value phase_diff_count to a count value phase_th_count indicative of the predefined threshold phase_th. If phase_diff_count is greater than phase_th_count, there is a synchronisation error between the input clock signal CLK_IN and the frame synchronisation signal FSYNC, which the phase alignment circuitry 260 corrects in current cycle of the input clock signal CLK_IN (i.e. before the start of the next cycle of the input clock signal CLK_IN), by extending the duration of a single cycle of the bit clock signal BCLK by a number of periods of the master clock signal MCLK equal to the difference between phase_diff_count and phase_th_count.

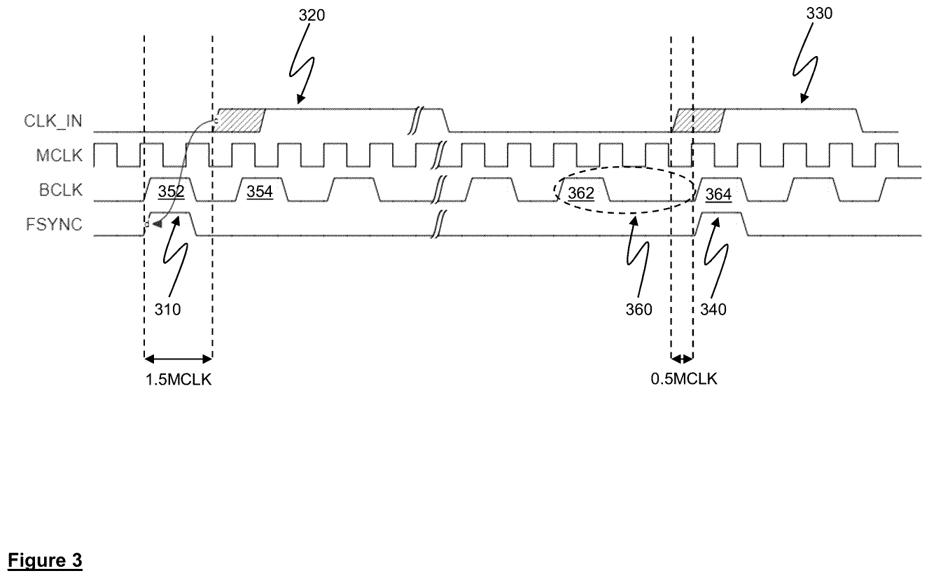

This approach is illustrated in FIG. 3, which is a timing diagram showing correction of a phase synchronisation error or misalignment between the input clock signal CLK_IN and the output frame synchronisation signal FSYNC.

As can be seen in FIG. 3, a rising edge of a first pulse 310 of the output frame synchronisation signal FSYNC leads a rising edge of a first pulse 320 of the input clock signal CLK_IN by one and a half periods of the master clock signal MCLK. A rising edge of a first pulse 352 of the output bit clock signal BLCK also leads the rising edge of the first pulse 310 of the input clock signal CLK_IN by one and a half periods of the master clock signal MCLK.

In this example the threshold phase_th is equal to half the period of the master clock MCLK, so the output frame synchronisation signal FSYNC and the input clock signal CLK_IN are out of phase by one period of the master clock signal MCLK. Similarly, the output bit clock signal BCLK and the input clock signal CLK_IN are out of phase by one period of the master clock signal MCLK.

The phase alignment circuitry 260 is operative to correct this synchronisation error in current cycle of the input clock signal CLK_IN (in this example in the period between the falling edge of the first pulse 320 and a rising edge of a next pulse 330 of the input clock signal CLK_IN), by adjusting the duration of a cycle of the output frame synchronisation signal FSYNC (i.e. by adjusting the duration of the period between the first pulse 310 of the output frame synchronisation signal FSYNC and a second pulse 340 of the output frame synchronisation signal FSYNC).

In the example shown in FIG. 3, this is achieved by extending the duration of a single cycle 360 of the bit clock signal BLCK by a number of periods of the master clock signal MCLK equal to the difference between phase_diff_count and phase_th_count, which in this example is one period of the master clock signal MCLK. More specifically, the period between two adjacent pulses 362, 364 of the bit clock signal BCLK is extended by one period of the master clock signal MCLK in this example, such that the period between all adjacent pulses (e.g. the first pulse 352 and a second pulse 354) of the bit clock signal BCLK has a duration equal to one period of the master clock signal MCLK, except the period between the pulses 362 and 364, which has a duration of two periods of the master clock signal MCLK.

The effect of this extension of the single cycle 360 of the bit clock signal BCLK is that a leading edge of a second pulse 340 of the output frame synchronisation signal FSYNC lags the leading edge of the second pulse of the input clock signal CLK_IN by half a period of the master clock signal MCLK, and thus correct synchronisation or phase alignment between the input clock signal CLK_IN and the output frame synchronisation signal FSYNC is restored. Similarly, a leading edge of the pulse 364 of the output bit clock signal BCLK lags the leading edge of the second pulse of the input clock signal CLK_IN by half a period of the master clock signal MCLK, and thus correct synchronisation or phase alignment between the input clock signal CLK_IN and the output bit clock signal BCLK is restored.

Thus, the approach adopted in the first mode of operation quickly restores correct synchronisation or phase alignment between the input clock signal CLK_IN and the output frame synchronisation signal FSYNC and between the input clock signal CLK_IN and the output bit clock signal BCLK.

However, a disadvantage of this approach is that it can give rise to audible artefacts such as pops in an audio output of a host device that incorporates the circuitry 200.

In applications or situations in which such audible artefacts are undesirable, the phase alignment circuitry 260 may operate in a second mode of operation in which any required correction is performed over a plurality of cycles of the output frame synchronisation signal FSYNC.

Thus, in the second mode of operation, the phase alignment circuitry 260 is again operable to measure the phase difference phase_diff, by counting a number of periods of the master clock MCLK between an edge (e.g. a rising edge) of the frame synchronisation signal FSYNC and a corresponding edge of the input clock signal CLK_IN. The phase alignment circuitry 260 is operative to compare the resulting count value phase_diff_count to a count value phase_th_count indicative of the predefined threshold phase_th. If phase_diff_count is greater than phase_th_count, there is a synchronisation error between the input clock signal CLK_IN and the frame synchronisation signal FSYNC.

In the second mode of operation, the phase alignment circuitry 260 is operative to correct this synchronisation error over a plurality of subsequent cycles of the output frame synchronisation signal FSYNC. This is achieved by adjusting the duration of one cycle of the bit clock signal BCLK per cycle of the output frame synchronisation signal FSYNC by a correction step of a predefined fixed duration step_size that does not correspond to the phase difference phase_diff. In this way, the phase difference is reduced by step_size in each subsequent cycle of the output frame synchronisation signal FSYNC, until the remaining phase difference is less than step_size. When the remaining phase difference is less than step_size, the duration of the next cycle of the output frame synchronisation signal FSYNC is extended by a duration corresponding to the remaining phase difference, by extending a cycle of the bit clock output signal BLCK by a duration corresponding to the remaining phase difference.

Thus, in the second mode of operation it takes longer (i.e. more cycles of the input clock signal CLK_IN and the output frame synchronisation signal FSYNC) to restore correct alignment or synchronisation between the input clock signal CLK_IN and the frame synchronisation signal FSYNC (and between the input clock signal CLK_IN and the output bit clock signal BLCK), but this is achieved without audible pops in an audio output of a host device.

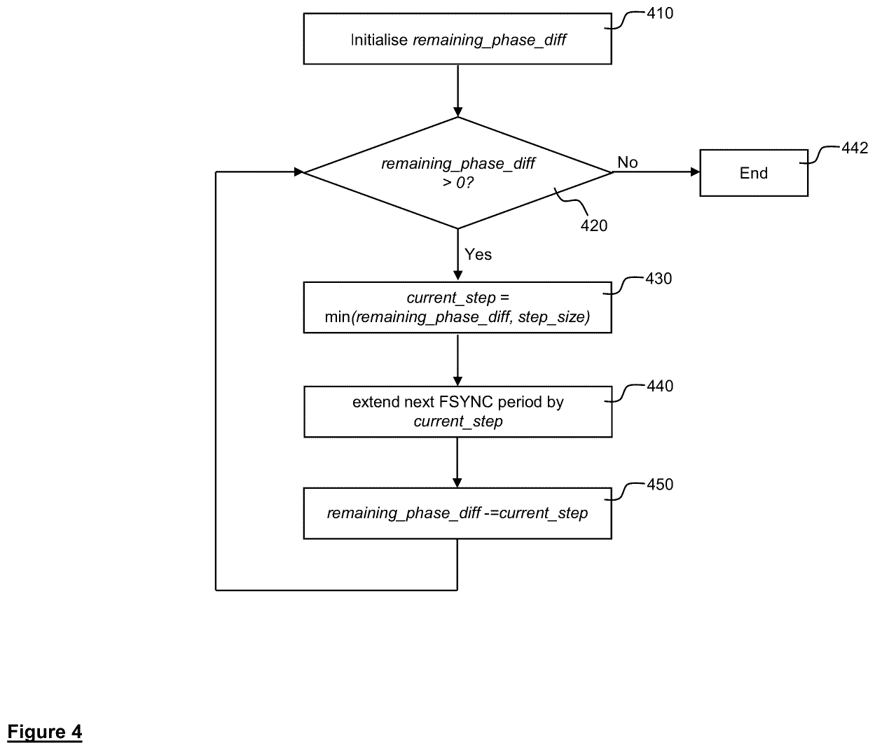

FIG. 4 is a flow chart illustrating steps in a method performed by the phase alignment circuitry 260 in the second mode of operation.

In an initialisation step 410, the phase alignment circuitry 260 initialises a variable remaining_phase_diff to a value equal to a duration of the measured phase difference phase_diff.

In a subsequent comparison step 420, the phase alignment circuitry 260 compares the value of remaining_phase_diff to 0, to check whether any phase difference still exists between the input clock signal CLK_IN and the output frame synchronisation signal FSYNC. If remaining_phase_diff is equal to 0, no such phase difference exists and the method ends (at step 442).

If remaining_phase_diff is greater than 0, a phase difference exists between the input clock signal CLK_IN and the output frame synchronisation signal FSYNC, so the phase alignment circuitry 260 proceeds to perform a selection step 430, to select the size of a correction step to be applied in the next period of the output frame synchronisation signal FSYNC.

In the selection step 430, the phase alignment circuitry 260 sets a variable current_step to the minimum of the predetermined fixed duration correction step step_size and remaining_phase_diff. Thus, if the duration of the remaining phase difference between the input clock signal CLK_IN and the output frame synchronisation signal FSYNC is greater than duration of the fixed duration correction step step_size, current_step is set to step_size, whereas if the duration of the remaining phase difference is less than step_size, current_step is set to remaining_phase_diff.

The phase alignment circuitry 260 then performs an extension step 440, in which it extends the next period of the output frame synchronisation signal FSYNC by a period equal to current_step, by extending the duration of a cycle of the bit clock signal BCLK (within the period of the next output frame synchronisation signal FSYNC) by a number of periods of the master clock signal MCLK equal to current_step.

The phase alignment circuitry 260 then (in step 450) decrements remaining_phase_diff by current_step before returning to the comparison step 420.

The phase alignment circuitry 260 continues to perform steps 420 to 450 to extend successive periods of the output frame synchronisation signal FSYNC by current_step until the phase difference between the input clock signal CLK_IN and the output frame synchronisation signal FSYNC has been corrected, i.e. until remaining_phase_diff is equal to zero.

Thus, the phase difference between the input clock signal CLK_IN and the output frame synchronisation signal FSYNC is corrected over a plurality of cycles of the output frame synchronisation signal FSYNC using a fixed-duration correction step.

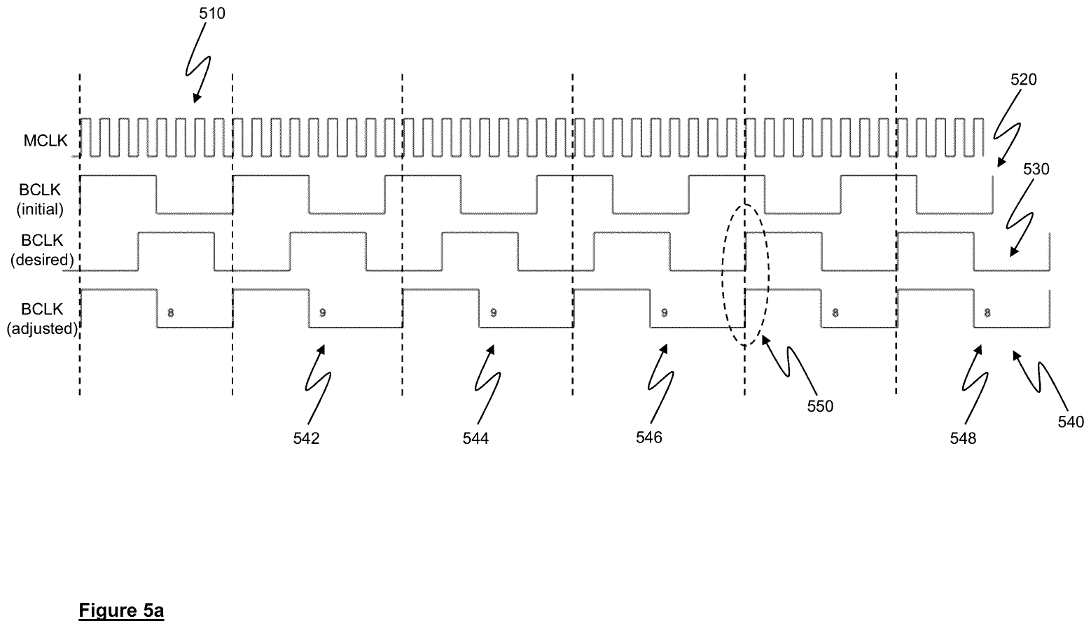

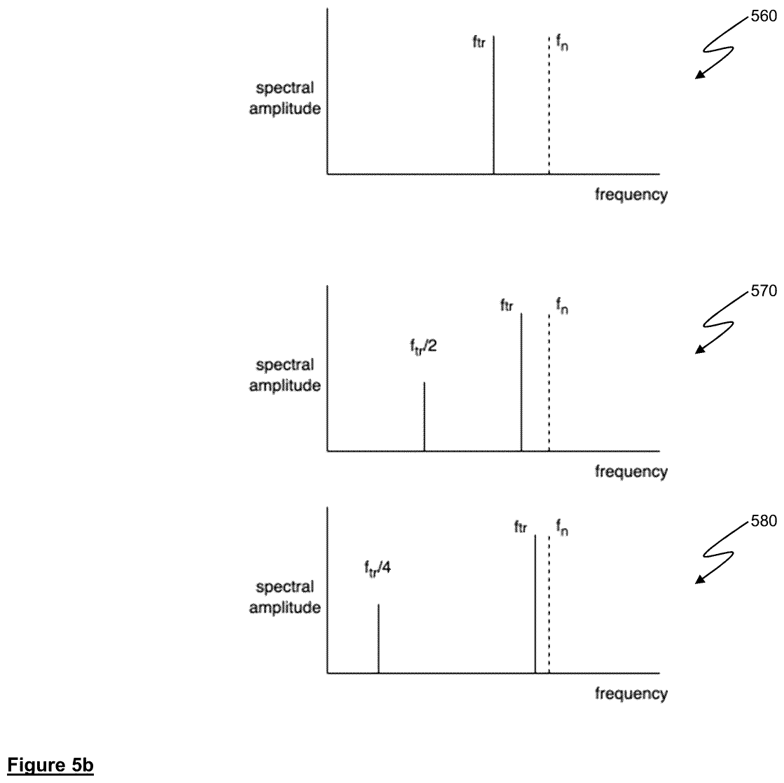

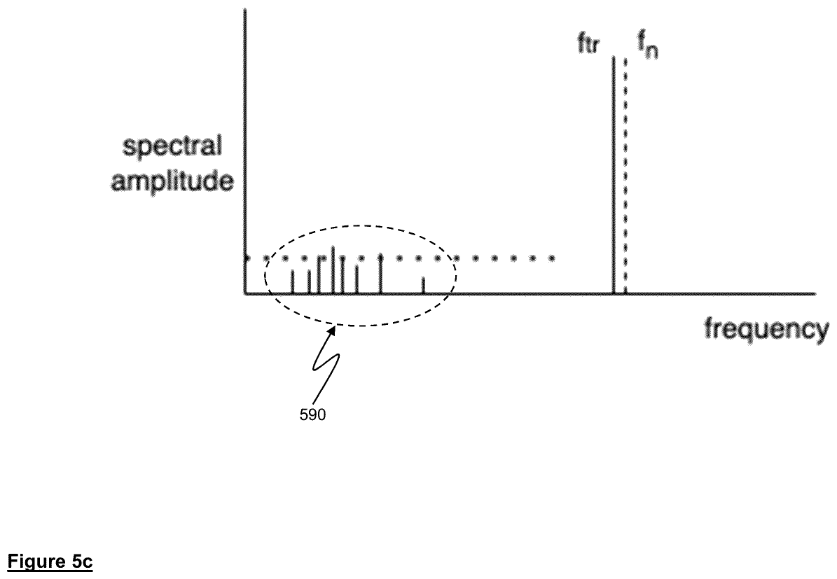

A disadvantage of extending the duration of a plurality of output bit clock BCLK cycles using a correction step of a fixed duration is that it can introduce unwanted spectral elements into the output bit clock signal BCLK, which can produce distortion in an audio output of a host device incorporating the circuitry 200, as will now be explained with reference to FIG. 5a.

FIG. 5a is a timing diagram showing: the master clock signal MCLK 510; an initial (i.e. unmodified) bit clock output signal 520 having a default phase; a desired bit clock output signal 530 having a phase that is different than the default phase of the initial bit clock output signal 520, to correct a phase error between an output frame synchronisation signal FSYNC and an input clock signal CLK_IN; and an adjusted bit clock output signal 540 having cycles of adjusted duration to align the phase of adjusted bit clock output signal 540 with that of the desired bit clock output signal 530.

As can be seen in FIG. 5a, the period of a cycle of the initial bit clock signal 520 is equal to the duration of eight cycles of the master clock signal MCLK 510. The initial bit clock signal 520 is out of phase with the desired bit clock output signal 530 required to correct the phase error between the output frame synchronisation signal FSYNC and the input clock signal CLK_IN. In the example shown in FIG. 5a, the durations of three consecutive cycles of the output bit clock BCLK are adjusted to achieve phase alignment between the adjusted bit clock output signal 540 and the desired bit clock output signal 530. Prior to phase adjustment, a cycle of the adjusted bit clock output signal 540 has a period equal to eight cycles of the master clock signal MCLK 510. Subsequent first, second, and third adjusted cycles 542, 544, 546 of the adjusted bit clock output signal 540 are each extended to have a period equal to nine cycles of the master clock signal MCLK 510. Subsequent cycles (e.g. cycle 548) of the adjusted bit clock output signal each have a period equal to eight cycles of the master clock signal MCLK 510. Thus, the adjusted bit clock output signal follows a cycle period sequence 8, 9, 9, 9, 8, 8, 8, 8, 8 . . . .

In this way, a transition in the phase of the adjusted bit clock output signal 540 to correspond to that of the desired bit clock output signal 530 can be achieved relatively quickly, in only three cycles of the bit clock output signal. However, because the average period of the bit clock output signal over the phase transition is 9 MCLK cycles, the frequency of the adjusted bit clock output signal varies between a default or nominal frequency fₙ (corresponding to the period of the initial bit clock output signal 520) and a lower transition frequency fₜᵣ (corresponding to the extended periods of the adjusted bit clock output signal 540). In the example shown in FIG. 5a, this variation leads to a frequency deviation of 1−(8/9) or 11.1%.

This frequency deviation may be reduced by performing the phase transition of the adjusted bit clock output signal more slowly, by modifying the sequence followed by the adjusted bit clock output signal 540 to alternate between cycles of a default duration (i.e. eight MCLK cycles in the example of FIG. 5a) and cycles of extended duration, e.g. to follow a sequence 8, 9, 8, 9, 8, 9, 8, 8, 8 . . . . Using this example sequence the same phase shift as described above is performed (over six cycles of the adjusted bit clock output signal), but the average period over the phase transition is (8+9+8+9+8+9)/6=8.5, so the frequency deviation is 1−(8.5/8) or 5.9%.

The frequency deviation may be further reduced by inserting more cycles of the default cycle duration between cycles of extended duration. For example, using the sequence 9, 8, 8, 8, 9, 8, 8, 8, 9, 8, 8, 8 . . . (i.e. three cycles of default duration between each cycle of extended duration), the average period over the phase transition is (9+8+8+8+9+8+8+8+9+8+8+8)/12=8.25, so the frequency deviation in this example is 1−(8.25/8) or 3.0%.

As noted above, these schemes introduce unwanted spectral elements into the adjusted bit clock output signal. FIG. 5b schematically illustrates these unwanted spectral components in plots of spectral amplitude vs frequency.

The plot 560 of FIG. 5b illustrates the frequency spectrum of the adjusted bit clock output signal 540 for the case where the number of MCLK cycles per bit clock pulse output follows the sequence 8, 9, 9, 9, 8, 8, 8. In this sequence the frequency of the bit clock output signal changes from fₙ to fₜᵣ for the duration of the phase transition, and then returns to fₙ.

The plot 570 of FIG. 5b illustrates the frequency spectrum of the adjusted bit clock output signal 540 for the case where the number of MCLK cycles per bit clock pulse output follows the sequence 8, 9, 8, 9, 8, 9, 8, 8, 8. In this sequence the frequency of the bit clock output signal switches between from fₙ to (8/9)*fₙ on each successive clock cycle, so the adjusted bit clock output signal is effectively frequency modulated at half of its average frequency for over the duration of the transition. This introduces spectral components at the modulation frequency (i.e. at fₜᵣ/2). Using this sequence the average frequency over the phase transition period is closer to the default or nominal frequency fₙ than when a sequence of three consecutive extended cycles is used, and so in the plot 570 the spectral component at fₜᵣ is closer in frequency to the default or nominal frequency fₙ than in the plot 560.

The plot 580 of FIG. 5b illustrates the frequency spectrum of the adjusted bit clock output signal 540 for the case where the number of MCLK cycles per bit clock pulse output follows the sequence 9, 8, 8, 8, 9, 8, 8, 8, 9, 8, 8, 8. In this sequence the frequency of the bit clock output signal switches between from fₙ to (8/9)*fₙ every fourth clock cycle, so the adjusted bit clock output signal is effectively frequency modulated at a quarter of its average frequency fₜᵣ over the duration of the transition. This introduces spectral components at the modulation frequency (i.e. at fₜᵣ/4). Using this sequence the average frequency over the phase transition period is closer again to the default or nominal frequency fₙ than when a sequence of three consecutive extended cycles is used, and so in the plot 580 the spectral component at fₜᵣ is closer in frequency to the default or nominal frequency fₙ than in the plot 570.

This frequency modulation of the adjusted bit clock output signal may be considered as phase noise or clock jitter. The additional spectral components (at fₜᵣ/2 in plot 570 and fₜᵣ/4 in plot 580) are undesirable if the resulting clock signal is used for digital to analog or analog to digital conversion (e.g. of audio signals), because they modulate the audio signal path and may distort the audio signal.

In any sequence in which extended cycles of the adjusted bit clock output signal appear at regular intervals (i.e. periodically) in the adjusted bit clock output signal, unwanted spectral components will be present. To avoid the occurrence of such unwanted spectral components, the extended cycles in the adjusted bit clock output signals may instead be distributed randomly within the adjusted bit clock output signal, i.e. the position of the extended cycles within the sequence followed by the adjusted bit clock output signal may be randomised by the phase alignment circuitry 260 (using, for example, a random noise generator to determine how may cycles of the initial bit clock output signal frequency appear between each pair of extended cycles in the adjusted bit clock output signal), such that there is no periodicity to the extended cycles in the adjusted bit clock output signal.

For example, the phase alignment circuitry 260 may cause the adjusted bit clock output signal to follow a sequence 8, 9, 8, 8, 8, 8, 9, 8, 8, 8, 8, 8, 8, 8, 8, 8, 9, 8, 8, 8, 8, 8, 8, 8, 8, 9, 8, 8, 8, 8, 8, 9, 8, 8, 8, 8, 8, 8, 8. In this sequence, the number of cycles at the default or nominal frequency between extended cycles follows the sequence 5, 10, 9, 6, 8, which does not have a pattern (and is a plausible output from a constrained random number generator). The use of random positions of the extended cycles in the adjusted bit clock output signal in this way effectively leads to frequency modulation of the adjusted bit clock output signal with noise, which breaks up any unwanted spectral components and instead yields spectral noise, as shown generally at 590 in FIG. 5c. This is significantly less problematic than the strongly tonal phase noise produced when the extended cycles in the adjusted bit clock output signal occur periodically as described above and shown in FIG. 5b.

Thus, randomising the positions of the extended cycles in the adjusted bit clock output signal is an effective way of avoiding the problems caused by unwanted spectral components that could otherwise arise if the extended cycles occur periodically in the adjusted bit clock output signal.

However, phase noise of the kind produced when the positions of the extended cycles are randomised in the bit clock output signal as described above may still be undesirable in the frequency ranges of the signal to be converted.

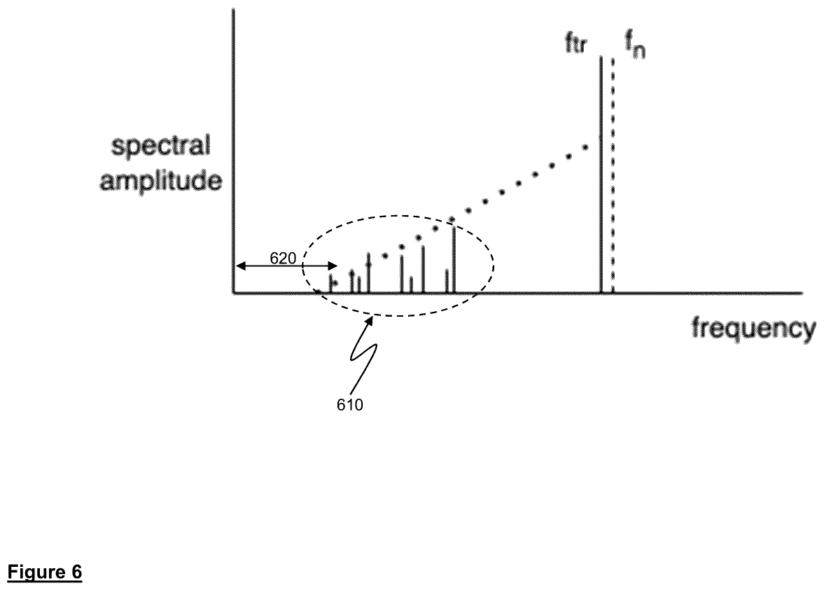

Thus, instead of using a spectrally flat random noise generator to randomise the positions of the extended cycles in the bit clock output signal, the phase alignment circuitry 260 may use a noise shaped random source such as a sigma-delta modulator to randomise the positions of the extended cycles within the adjusted bit clock output signal (e.g. by using such a noise shaped random source to determine how may cycles of the initial bit clock output signal frequency appear between each pair of extended cycles in the adjusted bit clock output signal). An example spectrum for such a scheme is shown in FIG. 6, from which it can be seen that the randomised modulation (shown generally at 610) approximates shaped noise, with no significant tonal content and low noise in a spectral range 620 of interest for signal conversion.

As an alternative to adjusting the period of cycles of the bit clock output signal BCLK by a fixed correction step size, in a third mode of operation of the phase alignment circuitry 260, any required correction is performed over a plurality of cycles of the output frame synchronisation signal FSYNC, with the size of the correction step (in terms of the number of master clock periods) being randomised for each cycle of the output frame synchronisation signal FSYNC in which correction is performed.

Thus, in the third mode of operation, the phase alignment circuitry 260 is again operable to measure the phase difference phase_diff, by counting a number of periods of the master clock MCLK between an edge (e.g. a rising edge) of the frame synchronisation signal FSYNC and a corresponding edge of the input clock signal CLK_IN. The phase alignment circuitry 260 is operative to compare the resulting count value phase_diff_count to a count value phase_th_count indicative of the predefined threshold phase_th. If phase_diff_count is greater than phase_th_count, there is a synchronisation error between the input clock signal CLK_IN and the frame synchronisation signal FSYNC, which the phase alignment circuitry 260 corrects over a plurality of subsequent phases of the input clock signal CLK_IN, by adjusting the duration of one or more cycles of the output frame synchronisation signal FSYNC using a random or pseudo-random correction step size.

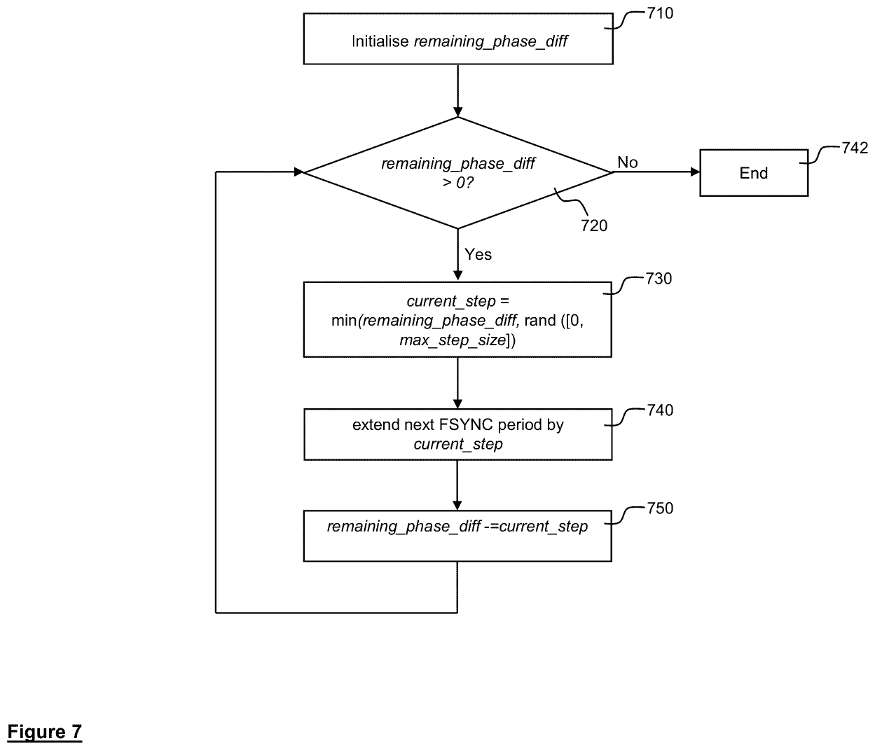

FIG. 7 is a flow chart illustrating steps in a method performed by the phase alignment circuitry 260 in the third mode of operation.

In an initialisation step 710, the phase alignment circuitry 260 initialises a variable remaining_phase_diff to a value equal to the measured phase difference phase_diff.

In a subsequent comparison step 720, the phase alignment circuitry 260 compares the value of remaining_phase_diff to 0, to check whether any phase difference still exists between the input clock signal CLK_IN and the output frame synchronisation signal FSYNC. If remaining_phase_diff is equal to 0, no such phase difference exists and the method ends (at step 742).

If remaining_phase_diff is greater than 0, a phase difference exists between the input clock signal CLK_IN and the output frame synchronisation signal FSYNC, so the phase alignment circuitry 260 proceeds to perform a selection step 730, to select the size of a correction step to be applied in the next period of the output frame synchronisation signal FSYNC.

In the selection step 730, the phase alignment circuitry 260 calculates a random or pseudo-random step size having a duration between 0 and a maximum step size max_step_size, and sets a variable current_step to the minimum of the calculated random step size and remaining_phase_diff. Thus, if the remaining phase difference between the input clock signal CLK_IN and the output frame synchronisation signal FSYNC is greater the duration of the calculated random or pseudo-random step size, current_step is set to the calculated random step size, whereas if the remaining phase difference is less than the calculated random step size, current_step is set to remaining_phase_diff.

The phase alignment circuitry 260 then performs an extension step 740, in which it extends the next period of the output frame synchronisation signal FSYNC by a period equal to current_step, by extending the duration of a cycle of the bit clock signal BCLK (within the period of the next output frame synchronisation signal FSYNC) by a number of periods of the master clock signal MCLK equal to current_step.

The phase alignment circuitry 260 then (in step 750) decrements remaining_phase_diff by current_step before returning to the comparison step 720.

The phase alignment circuitry 260 continues to perform steps 720 to 750 to extend successive periods of the output frame synchronisation signal FSYNC by current_step until the phase difference between the input clock signal CLK_IN and the output frame synchronisation signal FSYNC has been corrected, i.e. until remaining_phase_diff is equal to zero.

Thus, the phase difference between the input clock signal CLK_IN and the output frame synchronisation signal FSYNC is corrected over a plurality of cycles of the output frame synchronisation signal FSYNC using correction steps of random duration.

The three different modes of operation of the phase alignment circuitry 260 allows the alignment of the phase of the output frame synchronisation signal FSYN to the input clock signal CLK_IN to be optimised for different operational requirements such as minimum delay or least output distortion/best audio quality.

The phase alignment circuitry 260 (and thus also the circuitry 200) may thus be operable in one of a plurality of phase alignment modes. The plurality of phase alignment modes may include two or more of the above-described first, second and third modes of operation.

As explained in detail above, in the first mode of operation, phase alignment is performed using a single correction step of variable duration. The first mode of operation may thus be described as a single step alignment mode.

In the second mode of operation, phase alignment is performed using multiple correction steps of a fixed duration. The second mode of operation may thus be described as a multiple step alignment mode.

In the third mode of operation, phase alignment is performed using multiple correction steps of random or pseudo-random durations. The third mode of operation may thus be described as a random or pseudo-random step alignment mode.

It is to be appreciated that the present disclosure extends to phase alignment circuitry 260 that is operable in the third (random or pseudo pseudo-random step) alignment mode, and also to phase alignment circuitry 260 that is operable in the second (multiple step) alignment mode with random or pseudo random positioning of extended cycles of the output bit clock signal to correct phase error between the input clock signal and the output frame synchronisation signal.

The present disclosure also extends to an integrated circuit configured to receive an input clock signal (e.g. the input clock signal CLK_IN) and to generate an output bit clock signal BCLK and an output frame synchronisation signal FSYNC, where the output frame synchronisation signal FSYNC is phase aligned with the input clock signal CLK_IN.

Further, although the present disclosure has been described in terms of correcting phase error between an input clock signal and an output frame synchronisation signal, it will be appreciated by those of ordinary skill in the art that the principles of the present disclosure are equally applicable to phase alignment or synchronisation between an input clock signal and other types output signal, and are not limited to audio applications.

The circuitry described above with reference to the accompanying drawings may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, an automotive device, e.g. an automotive audio system, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog™ or VHDL (Very high speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. Circuitry for aligning a phase of an output signal with a phase of an input clock signal, the circuitry being operable in one of a plurality of phase alignment modes, wherein the plurality of phase alignment modes comprises two or more of:
a single step alignment mode;
a multiple step alignment mode; and
a random or pseudo-random step alignment mode.

2. Circuitry according to claim 1, wherein the output signal comprises a frame synchronisation output signal.

3. Circuitry according to claim 1, wherein the output signal comprises a bit clock output signal.

4. Circuitry according to claim 1, wherein the circuitry comprises phase alignment circuitry configured to:
determine a phase difference between a cycle of the input clock signal and a cycle of the output signal; and
apply one or more correction steps to correct the determined phase difference.

5. Circuitry according claim 4, wherein the phase alignment circuitry is configured to count a number of cycles of a master clock signal between an edge of the output signal and a corresponding edge of the input clock signal.

6. Circuitry according to claim 4, wherein:
in the single step alignment mode, the phase alignment circuitry is operative to extend a period of a single subsequent cycle of the output signal by a applying a single correction step having a duration corresponding to the determined phase difference.

7. Circuitry according to claim 5, wherein the period of the single subsequent cycle is extended by applying the single correction step to a single cycle of an output clock signal upon which the output signal is based.

8. Circuitry according to claim 7, wherein the output signal is an output frame synchronisation signal, and the output clock signal is an output bit clock signal.

9. Circuitry according to claim 4, wherein in the multiple step alignment mode the phase alignment circuitry is operable to:
extend a period of each of one or more subsequent cycles of the output signal by applying a correction step having a duration that does not correspond to the determined phase difference.

10. Circuitry according to claim 9, wherein in the multiple step alignment mode the phase alignment circuitry is operative to:
determine a correction step to be applied to a next cycle of the output signal to extend the period of the next cycle, based on a minimum between a predetermined correction step value and a value of a remaining phase difference between the cycle of the input clock signal and a cycle of the output signal.

11. Circuitry according to claim 10, wherein the period of the next cycle of the output signal is extended by applying the determined correction step to a cycle of an output clock signal upon which the output signal is based within the period of the next cycle of the output signal.

12. Circuitry according to claim 11, wherein the phase alignment circuitry comprises a random noise source for randomly or pseudo-randomly selecting the cycle of the output clock signal to which the determined correction step is applied.

13. Circuitry according to claim 12, wherein the random noise source comprises a noise shaped random noise source such as a sigma-delta modulator.

14. Circuitry according to claim 4, wherein in the random or pseudo-random step alignment mode the phase alignment circuitry is operative to:
extend a period of each of one or more subsequent cycles of the output signal by applying a correction step having a randomly or pseudo-randomly selected duration.

15. Circuitry according to claim 14, wherein in the random or pseudo-random step alignment mode the phase alignment circuitry is operative to:
determine a correction step to be applied to a next cycle of the output signal to extend the period of the next cycle, based on a minimum between a randomly or pseudo-randomly selected correction step duration and a duration of a remaining phase difference between the cycle of the input clock signal and a cycle of the output signal.

16. Circuitry according to claim 1, further comprising clock generator circuitry configured to receive the input clock signal and a frequency reference signal and to generate an output clock signal having a frequency of the input clock signal and jitter characteristics of the frequency reference signal.

17. Circuitry according to claim 16 wherein the clock generator circuitry comprises hybrid phase locked loop circuitry comprising an analog phase locked loop having a feedback path comprising a digital frequency locked loop.

18. Circuitry according to claim 16, wherein the circuitry is configured to generate a master clock signal based on the output clock signal generated by the clock generator circuitry.

19. Circuitry according to claim 4, wherein the circuitry is configured to generate a master clock signal, and wherein a duration of the one or more correction steps is based on a period of the master clock signal.

20. An integrated circuit comprising circuitry according to any of the claim 1.

21. A host device comprising circuitry according to claim 1.

22. A host device according to claim 21, wherein the host device comprises a laptop, notebook, netbook or tablet computer, a gaming device, a games console, a controller for a games console, a virtual reality (VR) or augmented reality (AR) device, a mobile telephone, a portable audio player, a portable device, an automotive device, an automotive audio system, an accessory device for use with a laptop, notebook, netbook or tablet computer, a gaming device, a games console a VR or AR device, a mobile telephone, a portable audio player or other portable device.

23. A clock generator integrated circuit having:
an input for receiving an input clock signal;
a first output for outputting a bit clock output signal; and
a second output for outputting a frame synchronisation signal,
wherein the clock generator integrated circuit is configured to maintain a phase alignment between the input clock signal and the frame synchronisation output signal, and/or between the input clock signal and the bit clock output signal.

24. Phase alignment circuitry for aligning a phase of an output signal with a phase of an input clock signal, the phase alignment circuitry being configured to:
determine a phase difference between a cycle of the input clock signal and a cycle of the output signal; and
extend a period of each of one or more subsequent cycles of the output signal by applying a correction step having a randomly or pseudo-randomly selected duration, to align a phase of the output signal with a phase of the input signal.

25. Phase alignment circuitry for aligning a phase of an output signal with a phase of an input clock signal, the phase alignment circuitry being configured to:
determine a phase difference between a cycle of the input clock signal and a cycle of the output signal; and
extend a period of each of one or more subsequent cycles of the output signal by applying a correction step having a duration that does not correspond to the determined phase difference to a cycle of an output clock signal upon which the output signal is based within the period of the next cycle of the output signal,
wherein phase alignment circuitry is configured to select the cycle of the output clock signal to which the correction step is applied randomly or pseudo-randomly.
